(19) United States
(12) Patent Application Publication
(10) Pub. No.: US 2026/0238180 A1
(43) Pub. Date: Aug. 13, 2026

(54) BULK ACOUSTIC WAVE STRUCTURES WITH CONDUCTIVE BRIDGE STRUCTURES AND FABRICATION METHODS THEREOF

(71) Applicant: Qorvo US, Inc., Greensboro, NC (US)

(72) Inventors: Alireza TAJIC, Snoqualmie, WA (US); Jyothi Swaroop SADHU, Sanford, FL (US); Paul STOKES, Orlando, FL (US); Mohammad Jafar MODARRES-ZADEH, Longwood, FL (US)

(21) Appl. No.: 19/152,386

(22) PCT Filed: Feb. 21, 2024
(86) PCT No.: PCT/US2024/016696

§ 371 Date: Jul. 30, 2025

Related U.S. Application Data
(60) Provisional application No. 63/487,233, filed on Feb. 27, 2023.

(51) Int. Cl. H03H 9/13; H03H 9/02; H03H 9/15

(52) U.S. Cl. CPC H03H 9/13; H03H 9/02015; H03H 9/15

(57) ABSTRACT

A bulk acoustic wave (BAW) resonator structure is provided. The BAW resonator structure includes a transducer that includes a first electrode, a second electrode, a piezoelectric layer between the first electrode and the second electrode, a dielectric layer in contact with the piezoelectric layer on a surface of the piezoelectric layer, and a conductive layer over the first electrode. The transducer also includes a conductive bridge portion in contact with the first electrode, the conductive layer, and over and in contact with the dielectric layer. The conductive bridge portion and the conductive layer form a conductive bridge structure between ends of the first electrode.

### CROSS-REFERENCE TO RELATED APPLICATIONS

The present application claims the benefit of U.S. Provisional Application No. 63/487,233, filed Feb. 27, 2023, which is incorporated herein by reference in its entirety

### FIELD OF THE INVENTION

This disclosure relates to bulk acoustic wave (BAW) structures. In particular, this disclosure relates to BAW structures with conductive bridge structures between electrodes and reflector layers.

### BACKGROUND

Acoustic resonators, e.g., particularly Bulk Acoustic Wave (BAW) resonators or BAW filters, are used in high-frequency communication applications such as 3^{rd} Generation (3G), 4^{th} Generation (4G), and 5th Generation (5G) wireless devices. In particular, a BAW resonator is often employed to provide a flat passband, steep filter skirts, and squared shoulders at the upper and lower ends of the passband, and provide excellent rejection outside of the passband in a filter network. BAW resonators also have relatively low insertion loss, tend to decrease in size as the frequency of operation increases, and are relatively stable over wide temperature ranges. These wireless devices often support various communication means such as cellular, wireless fidelity (Wi-Fi), Bluetooth, and/or near field communications, and accordingly, high performance of the BAW resonators are needed.

To meet filtering requirements in certain applications, a BAW resonator that operates at higher frequencies often has thinner electrodes and/or a smaller resonator area. As a result, the BAW resonator can have higher electrical loss, which can negatively affect its performance. Thus, there is a need to improve the performance of the BAW resonators.

### SUMMARY

Aspects of the invention include a BAW resonator structure. The BAW resonator structure includes a transducer that includes a first electrode, a second electrode, a piezoelectric layer between the first electrode and the second electrode, a dielectric layer in contact with the piezoelectric layer on a surface of the piezoelectric layer, and a conductive layer over the first electrode. The transducer also includes a transducer that includes a conductive bridge portion in contact with the first electrode, the conductive layer, and over and in contact with the dielectric layer. The conductive bridge portion and the conductive layer form a conductive bridge structure between ends of the first electrode.

In some embodiments, the conductive bridge portion is in contact with the first electrode, and includes a same conductive material as the first electrode.

In some embodiments, the transducer further includes a second dielectric layer in contact with the piezoelectric layer on a second surface of the piezoelectric layer. In some embodiments, a second conductive bridge structure over and in contact with the second dielectric layer, and in contact with the second electrode. The second conductive bridge structure includes a same conductive material as the second electrode.

In some embodiments, in a horizontal direction, a length of the conductive bridge portion is smaller than a length of the second conductive bridge portion. In some embodiments, in a vertical direction, a projection of the conductive bridge structure is partially overlapped with a projection of the second conductive bridge portion. In some embodiments, a boundary between the conductive bridge portion and the first electrode is aligned with a boundary between the second conductive bridge portion and the second electrode.

In some embodiments, in a horizontal direction, a length of the conductive bridge portion is smaller than a length of the second conductive bridge portion. In some embodiments, in a vertical direction, a projection of the conductive bridge portion has no overlap with a projection of the second conductive bridge portion.

In some embodiments, in a vertical direction, a projection of the first electrode is partially overlapped with a projection of the dielectric layer. In some embodiments, a projection of the second electrode has no overlap with a projection of the second dielectric layer.

In some embodiments, the first electrode has a first thickness in an active region and a frame region surrounding the active region, and has a second thickness outside the active region and the frame region, the second thickness being greater than the first thickness. In some embodiments, the second electrode has a same thickness in the active region, the frame region, and outside the frame region.

In some embodiments, the transducer further includes a first insulating layer over and in contact with the first electrode in the active region and the frame region. The first insulating layer has a first thickness in the active region and a second thickness in the frame region, the first thickness being greater than the second thickness.

In some embodiments, the transducer further includes a second insulating layer over and in contact with the second electrode in the active region and the frame region. The second insulating layer may have a same thickness in the active region and the frame region.

In some embodiments, an angle between a side surface of the first dielectric layer and a vertical direction is between about 30 degrees and about 60 degrees. In some embodiments, an angle between a side surface of the second dielectric layer and the vertical direction is between about 5 degrees and about 15 degrees.

In some embodiments, an angle between a side surface of the first insulating layer and a vertical direction is between about 30 degrees and about 50 degrees.

In some embodiments, an angle between a side surface of the second insulating layer and a vertical direction is between about 5 degrees and about 15 degrees.

In some embodiments, in a vertical direction, a thickness of the first dielectric layer is between about 20 nm and about 200 nm.

In some embodiments, the transducer further includes one or more insulating layers each in contact with a respective one of the first electrode and the second electrode. The one or more insulating layers each may include an air gap.

In some embodiments, the transducer further includes a conductive layer in contact with the second insulating layer. In a vertical direction, a surface of the second conductive bridge portion may be located between a first surface and a second surface of the conductive layer.

In some embodiments, the transducer further includes an aluminum nitride-tungsten-aluminum nitride structure located between the second dielectric layer and the second conductive bridge portion.

In some embodiments, an angle between a side surface of the conductive bridge portion and a vertical direction is approximately zero, and an angle between a side surface of the second conductive bridge portion and the vertical direction is approximately zero.

In some embodiments, in a vertical direction, a projection of the conductive bridge portion is aligned with a projection of the second conductive bridge portion.

In some embodiments. the transducer further includes an insulating layer over and in contact with at least one of the first and second electrode layers, the insulating layer being in contact with a respective conductive bridge portion. An interface between the insulating layer and the respective conductive bridge portion may be aligned with the vertical direction.

In some embodiments, the transducer further includes a pair of reflective layers over each of the first electrode and the second electrode and conductively connected to a respective conductive bridge that is in contact with the respective electrode. The pair of reflective layers may include tungsten layer and an aluminum copper layer.

### BRIEF DESCRIPTION OF THE DRAWINGS

FIGS. 1A and 1B each illustrates part of an exemplary BAW structure, according to embodiments of the present disclosure.

FIG. 1C illustrates a performance chart of the BAW structures shown in FIGS. 1A and 1B, according to embodiments of the present disclosure.

FIGS. 2A-2D each illustrates part of another exemplary BAW structure, according to embodiments of the present disclosure.

FIG. 2E illustrates performance charts of the BAW structures shown in FIGS. 2A-2D, according to embodiments of the present disclosure.

FIGS. 3A and 3B each illustrates part of another exemplary BAW structure, according to embodiments of the present disclosure.

FIGS. 4A and 4B each illustrates part of another exemplary BAW structure, according to embodiments of the present disclosure.

FIGS. 5A and 5B each illustrates part of another exemplary BAW structure, according to embodiments of the present disclosure.

FIG. 6 illustrates a flowchart of an exemplary fabrication process for forming a BAW structure, according to embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., ±10%, ±20%, or ±20% of that value, or ±30%).

Reference will now be made in greater detail to various embodiments of the subject matter of the present disclosure, some embodiments of which are illustrated in the accompanying drawings.

Efforts have been made to improve the performance of BAW resonators. For example, to meet filtering requirements in certain applications, thinner electrodes and/or smaller resonator areas have been adopted in BAW resonators for those operating at higher frequencies (e.g., greater than 5 GHz). However, reducing electrode thickness may result in increased resistance and/or electrical loss. Also, reducing resonator areas results in cascading multiple resonators in series to handle high power levels, thereby adding more resistance and/or electrical loss. In some applications, materials with high electrical conductivity (e.g., aluminum copper (AlCu)) are made thicker to reduce electrical losses, but doing so can result in increased acoustic losses because these materials are typically acoustically lossy, and larger thicknesses cause larger fractions of energy (stress/strain) in these layers.

To reduce the electrical loss in BAW resonators, embodiments of the present disclosure provide BAW structures, e.g., BAW resonators/filters, with reduced electrical loss compared to an existing BAW resonator. A disclosed BAW structure can also have comparable/improved resonating performance (e.g., quality factor or Q factor) compared to an existing BAW resonator. The BAW structure has a piezoelectric layer, a pair of electrodes sandwiching the piezoelectric layer, and one or more Bragg reflector stacks each over a respective electrode. The BAW structure also has at least one conductive bridge structure (e.g., a conductive loop) between the ends of an electrode. A conductive bridge structure includes a metallic portion of a Bragg reflector stack and a conductive bridge portion that is conductively connected to an end of an electrode, forming an electrical loop and reducing electrical loss of the BAW structure. The metallic portion of the Bragg reflector stack may include one or more Bragg reflector layers that are conductive. For example, the metallic portion may include the entire Bragg reflector stack (e.g., formed of conductive layers) or one or more of the Bragg reflector layers. The dimensions and/or locations of the parts in the disclosed BAW structure are optimized to minimize the electrical loss while maintaining/improving the acoustic performance. For example, the conductive bridge structure can reduce electrical resistance, heat resistance, and/or ohmic losses of the BAW structure, while having comparable or improved acoustic performance.

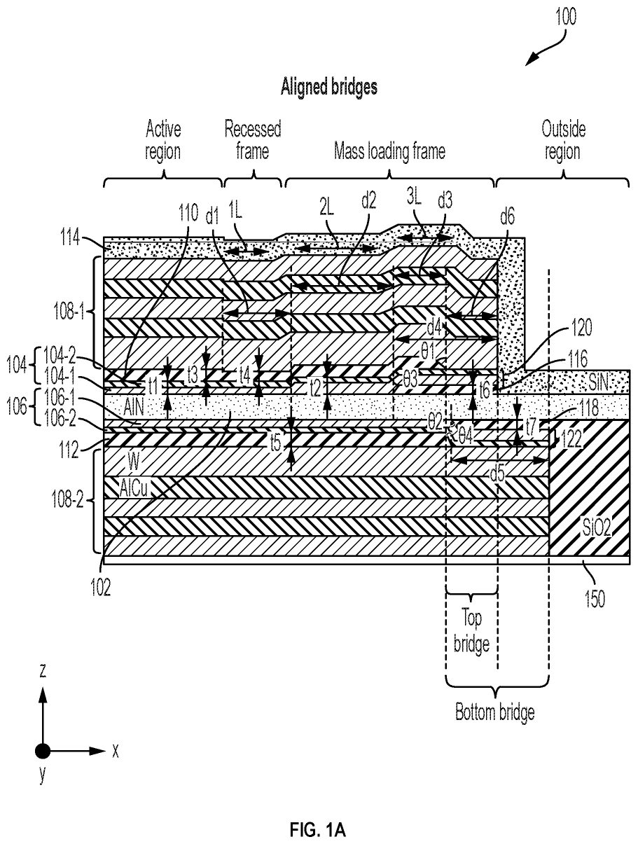

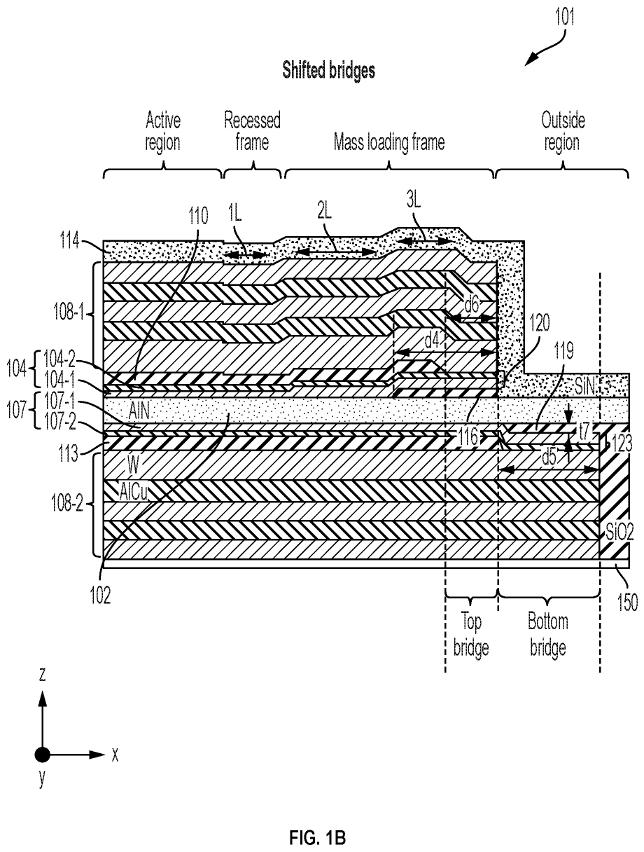

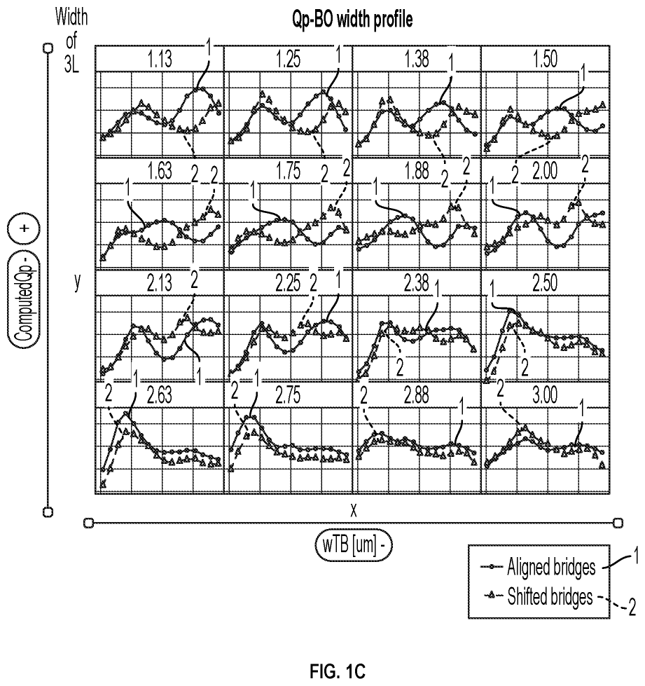

In the disclosed BAW structure, an electrode and a dielectric layer, in contact with each other, are disposed on the piezoelectric layer. The conductive bridge portion may be located outside the active/resonating region, and may be an extension of the electrode. The conductive bridge portion may be disposed over the dielectric layer, and may be in contact with a Bragg reflector layer (e.g., a metallic portion of the Bragg reflector stack over the electrode) such that the electrode is conductively connected to the Bragg reflector stack. The conductive bridge portion may partially or fully cover the dielectric layer. In some embodiments, the BAW structure includes two conductive bridge portions, each being an extension of a respective electrode. For example, a first conductive bridge portion (e.g., an extension of the first/top electrode) may partially cover a first dielectric layer, and a second conductive bridge portion (e.g., an extension of the second/bottom electrode) may fully cover a second dielectric layer. In some embodiments, the first conductive bridge portion and the second conductive bridge portion may partially or fully overlap vertically. For example, the first conductive bridge portion and the second conductive bridge portion are aligned with each other in the vertical direction. In some embodiments, in an “aligned bridges” configuration (as shown in FIG. 1A), the boundary between the first conductive bridge portion and the first/top electrode (e.g., or the end of the first conductive bridge portion that faces the active region) is vertically aligned with the boundary between the second conductive bridge portion and the second/bottom electrode (e.g., or the end of the second conductive bridge portion that faces the active region). In some embodiments, in an “shifted bridges” configuration (as shown in FIG. 1B), the first conductive bridge portion and the second conductive bridge portion have no overlap, and the second conductive bridge portion is disposed further away from the active region than the first conductive bridge portion. In some embodiments, the end of the first conductive bridge portion that faces away from the active region is vertically aligned with the end of the second conductive bridge portion that faces the active region. In some embodiments, the bottom surface of the second conductive bridge portion is located between the top and bottom surfaces of the Bragg reflector layer that is in contact with the second electrode. In some embodiments, the BAW structure includes a protection structure disposed between the second conductive bridge portion and the second dielectric layer. The protection structure may include an aluminum nitride-tungsten-aluminum nitride structure.

An insulating layer is disposed between each electrode and the respective Bragg reflector stack. An end of the insulating layer, facing away from the active region, may function as the boundary between the electrode and the respective conductive bridge portion. In some embodiments, a side surface of the insulating layer, facing away from the active region, may be in contact with the Bragg reflector layer that is in contact with the respective conductive bridge portion. In some embodiments, the side surface of the insulating layer may be in contact with the respective conductive bridge portion. For example, the angle between the side surface of the insulating layer and the vertical direction can be about zero degrees. The insulating layer can then be in contact with the respective conductive bridge portion on the side surface. Because the insulating layer and the conductive bridge portion may include materials that are acoustic similar, the scattering of the acoustic energy (e.g., at the interface between the insulating layer and the conductive bridge portion) is reduced/minimized. For example, the insulating layer may include silicon oxide, and the conductive bridge portion may include aluminum copper, which is acoustically similar to silicon oxide. The BAW resonator may have two insulating layers, e.g., a first insulating layer over the first electrode and a second insulating layer over the second electrode. In some embodiments, both of the insulating layers include silicon oxide. In some embodiments, one or both of the insulating layers may include an air gap/cavity. In addition to improving the electrical loss, the air gap may help confine the acoustic energy in the piezoelectric layer, and thus improve the acoustic coupling of the BAW structure.

In some embodiments, the BAW structure include one or more regions surrounding the active region to help improve the lateral confinement of acoustic energy and quality factor. The lengths and/or thicknesses of these regions are optimized to improve the acoustic performance (quality factor). For example, the BAW structure may include a recessed frame region in contact with and surrounding the active region. The recessed frame region is defined by the part of the top insulating layer that has a reduced thickness than that in the active region. The BAW structure may also include an inner border ring region in contact with and surrounding the recessed frame region. The inner border ring region is defined by the part of the first electrode that has an increased thickness than that of the active region. The BAW structure may further include an outer border ring region in contact with and surrounding the inner border ring region. The outer border ring region is defined by the part of the insulating layer over the dielectric layer.

In the present disclosure, the locations and/or geometric parameters of the electrodes, the conductive bridge portions, the insulating layers, and the dielectric layers are adjusted to optimize the performance, e.g., minimized electrical loss and comparable quality factor, of the BAW structure. For example, the length of a first dielectric layer may be between about 0.5 μm to about 4 μm, and the length of a second dielectric layer may be between about 1 μm to about 4 μm. In some embodiments, the angle between the side surface of the first dielectric layer and the vertical direction is about 30 degrees to about 60 degrees, and the angle between the side surface of the second dielectric layer and the vertical direction is about 5 degrees to about 15 degrees. In some embodiments, the angle between the side surface of the first insulating layer and the vertical direction is about 30 degrees to about 50 degrees, and the angle between the side surface of the second insulating layer and the vertical direction is about 5 degrees to about 15 degrees. In some embodiments, the length of the recessed frame region is between about 0.5 μm and about 4 μm, and the thickness of the first insulating layer in the recessed frame region is between about 5 nm to about 50 nm less than that of the first insulating layer in the active region. Details of the geometric parameters of various layers are described below in view of the figures.

FIGS. 1A, 1B, 2A-2D, 3A, 3B, 4A, 4B, 5A, and 5B illustrate exemplary BAW structures each having at least one conductive bridge portion. FIG. 1A illustrate exemplary BAW structure 100 with two conductive bridge portions, each over a respective dielectric layer, according to some embodiments. BAW structure 100 may be referred to as an “aligned bridges” configuration. BAW structure 100 may include a transducer that includes a piezoelectric layer 102, and a first electrode 104 (e.g., a top electrode) and a second electrode 106 (e.g., a bottom electrode) each in contact with piezoelectric layer 102. BAW structure 100 may include a substrate 150 on which the transducer is disposed. Substrate 150 may include a suitable material such as a semiconductor material (e.g., silicon), glass, plastic, or a combination thereof. Piezoelectric layer 102 may include a suitable piezoelectric material such as aluminum nitride (AlN), zinc oxide (ZnO), aluminum scandium nitride (AlScN) and/or other suitable materials. In some embodiments, piezoelectric layer 102 includes AlN. First electrode 104 and second electrode 106 may each include one or more suitable conductive materials, and may have a single-layer or a multi-layer structure. For example, first electrode 104 and second electrode 106 may each include one or more of copper (Cu), tungsten (W), aluminum copper (AlCu), molybdenum (Mo), and/or platinum (Pt). In some embodiments, first electrode 104 includes a first metal layer 104-1 in contact with piezoelectric layer 102, and a second metal layer 104-2 in contact with first metal layer 104-1. In some embodiments, second electrode 106 includes a first metal layer 101-1 in contact with piezoelectric layer 102, and a second metal layer 106-2 in contact with first metal layer 106-1. In some embodiments, first metal layer 104-1 and first metal layer 106-1 each includes W, and second metal layer 104-2 and second metal layer 106-2 each includes AlCu. A first insulating layer 110 and a second insulating layer 112 may be respectively disposed in contact with first electrode 104 (or second metal layer 104-2) and second electrode 106 (or second metal layer 106-2). In the present disclosure, the part of electrode material(s) covered by the respective insulating layer is referred to as the electrode, and the part of the electrode material extending beyond the coverage of the respective insulating layer is referred to as a conductive bridge portion. As shown in FIG. 1A, first electrode 104 may be covered by first insulating layer 110, and second electrode 106 may be covered by second insulating layer 112. First insulating layer 110 and second insulating layer 112 may each include a suitable insulating material such as silicon oxide, silicon nitride, silicon oxynitride, and/or epoxy.

BAW structure 100 may also include one or more Bragg reflector stacks each disposed over an electrode. First insulating layer 110 and second insulating layer 112 may each separate the electrode and respective the Bragg reflector stack(s). In some embodiments, BAW structure 100 includes a first Bragg reflector stack 108-1 over (e.g., in contact with) first insulating layer 110, and a second Bragg reflector stack 108-2 over (e.g., in contact with) second insulating layer 112. Each of first Bragg reflector stack 108-1 and second Bragg reflector stack 108-2 includes alternating a plurality of first reflective layers and second reflective layers. The first reflective layers and the second reflective layers may include one or more conductive materials of sufficiently high reflectivity and desirably low electrical resistance. In some embodiments, the first reflective layer includes W and the second reflective layer includes AlCu. Each of first Bragg reflector stack 108-1 and second Bragg reflector stack 108-2 may include one or more W-AlCu pairs. It should be noted that, first Bragg reflector stack 108-1 and second reflector stack 108-2 may include any suitable number of W-AlCu pairs, depending on the design. For example, first Bragg reflector stack 108-1 and second reflector stack 108-2 may each include at least five W-AlCu pairs, although the specific number is not limited by the embodiments/figures of the present disclosure. In some embodiments, the first reflective layer and the second reflective layer can also include other suitable conductive materials such as Cu, Mo, and/or Pt. BAW structure 100 may further include a passivation layer 114 that covers the exterior of BAW structure 100. Passivation layer 114 may include one or more insulating materials such as silicon oxide, silicon nitride, silicon oxynitride, or a combination thereof.

BAW structure 100 may include an active region, a mass loading frame region, and an outside region, as shown in FIG. 1A. The active region may be referred to the preferred region in which most of the acoustic energy is stored. The mass loading region may be referred to the thickened region surrounding the active region and may help reduce the scattering of the acoustic energy, e.g., improving the confinement of acoustic energy in the active region. In some embodiments, the loading region includes a mass loading frame that includes an inner boarder ring (“2L”) region defined by the increased thickness of first metal layer 104-1 (or first electrode 104), and an outer boarder ring (“3L”) region defined by the length of first insulating layer 110 extending outside the inner boarder ring region. The outer boarder ring region may surround the inner boarder ring region, which surrounds the active region. In some embodiments, the loading region further includes a recessed frame (“1L”) region in contact with and surrounding the active region. The inner boarder ring region may surround the recessed frame region. The recessed frame region may be referred to the region in which first insulating layer 110 has a reduced thickness compared to that in the active region. Piezoelectric layer 102, top and second electrodes 104 and 106, and first and second insulating layers 110 and 112 may extend in the active region, the recessed region, the inner boarder ring region, and the outer boarder ring region. First dielectric layer 116 may be disposed in the outer boarder ring region, and second dielectric layer 118 may be disposed outside the outer boarder ring region and partially in the outside region. In the “aligned bridges” configuration as shown in FIG. 1A, the ends of first insulating layer 110 and second insulating layer 112, facing away from the active region, are aligned in the vertical direction. In some embodiments, second insulating layer 112 and second electrode 106 extend through active region, recessed frame region, and in the outer boarder ring region. In the “aligned bridges” configuration as in BAW structure 100, the first insulating layer 110 and the first dielectric layer 116 overlap in the outer boarder ring region.

In some embodiments, a length d1 (e.g., in the x-direction) of the recessed frame region may be between about 0.5 μm and about 4 μm. In some embodiments, a length d2 of the inner border ring may be between about 0.25 μm and about 2 μm. In some embodiments, the outer boarder ring has a length d3 between about 0.5 μm and about 3 μm. As shown in FIG. 1A, in the active region and the recessed frame region, a thickness of first electrode 104 is t1 (e.g., unchanged). In the inner boarder ring, a thickness of first electrode 104 is t2 and is greater than t1. In some embodiments, t2 is between about 10% to about 30% greater than t1. As shown in FIG. 1A, first insulating layer 110 has a thickness t3 in the active region, and a thickness of t4 in the recessed frame region, where t4 is about 3% to about 15% less than t3. In some embodiments, a thickness t5 of second insulating layer 112 is unchanged in the active region and the loading region.

BAW structure 100 may include a first dielectric layer 116 on piezoelectric layer 102 and on the same side as first electrode 104, and a second dielectric layer 118 on piezoelectric layer 102 and on the same side as second electrode 106. The extension of the respective electrode (or the same material of the electrode) may be disposed over and may cover the respective dielectric layer, forming the respective conductive bridge portion. In some embodiments, the vertical projections (e.g., in the z-direction) of first dielectric layer 116 and second dielectric layer 118 may partially overlap. As shown in FIG. 1A, first electrode 104 may be disposed on (e.g., partially cover) first dielectric layer 116, and is in contact with a first conductive bridge portion 120. First conductive bridge portion 120 may also partially cover first dielectric layer 116. Second conductive bridge portion 122 may fully cover second dielectric layer 118, and may be in contact with second electrode 106 at the edge of second dielectric layer 118. In some embodiments, a bottom surface of second conductive bridge portion 122 is coplanar with the bottom surface of second insulating layer 112 (or the top surface of the Bragg reflector layer in contact with second insulating layer 112). Fist conductive bridge portion 120 and second conductive bridge portion 122 may have the same material(s) as first electrode 104 and second electrode 106, respectively. For example, first conductive bridge portion 120 and second conductive bridge portion 122 may each have a layer of W (e.g., a first portion) in contact with the respective dielectric layer (e.g., 116 or 118), and have a layer of AlCu (e.g., a second portion) on the layer of W. First conductive bridge portion 120 and second conductive bridge portion 122 may each be in contact with a Bragg reflector layer (e.g., W) in the Bragg reflector stacks 108-1 and 108-2, respectively.

The lengths of first conductive bridge portion 120 and second conductive bridge portion 122 may each be determined based on the part of the electrode material over the respective dielectric layer and not covered by the respective insulating layer. In some embodiments, first conductive bridge portion 120 partially covers the top surface (e.g., a flat surface) of first dielectric layer 116. In some embodiments, second conductive bridge portion 122 fully covers the top surface (e.g., a flat surface) and the side surface (e.g., a sloped surface) of second dielectric layer 118. For example, as shown in FIG. 1A, a length d4 (e.g., in the x-direction) of first dielectric layer 116 may be between about 0.5 μm and about 4 μm, and a length d5 of second dielectric layer 118 may be between about 1 μm and about 4 μm. First conductive bridge portion 120 may include the conductive material(s) outside the outer boarder ring region and a length d6 of first conductive bridge portion 120, e.g., not covered (e.g., exposed) by first insulating layer 110, may be between about 0.5 μm to about 1 μm. In some embodiments, d5 is greater than d6. Second conductive bridge portion 122 is not covered by second insulating layer 112, and includes the conductive material(s) outside the outer boarder ring region. A length of second conductive bridge portion 122 is d5, same as that of second dielectric layer 118. In some embodiments, first insulating layer 110, second insulating layer 112, first dielectric layer 116, and second dielectric layer 118 may each have a sloped side surface. In some embodiments, an angle θ1 between the side surface of first insulating layer 110 and the vertical direction (e.g., the z-direction) is between about 30 degrees and about 50 degrees, and an angle θ2 between the side surface of second insulating layer 112 and the vertical direction is between about 5 degrees and about 15 degrees. In some embodiments, an angle θ3 between the side surface of first dielectric layer 116 and the vertical direction is between about 30 degrees and about 60 degrees, and an angle θ4 between the side surface of second dielectric layer 118 and the vertical direction is between about 5 degrees and about 15 degrees. In some embodiments, a thickness t6 of first dielectric layer 116 is between about 20 nm and about 200 nm. In some embodiments, a thickness t7 of second dielectric layer 118 is between about 40 nm and about 400 nm.

FIG. 1B illustrate another exemplary BAW structure 101 with a pair of conductive bridge portions, according to some embodiments. BAW structure 101 may be referred to as a “shifted bridges” configuration. Different from BAW structure 100, BAW structure 101 may include a second dielectric layer 119 “shifted” from first dielectric layer 116 such that the vertical projections of first dielectric layer 116 and second dielectric layer 119 has no overlap. In some embodiments, a second conductive bridge portion 123, covering second dielectric layer 119, is shifted from first conductive bridge portion 120 such that the vertical projections of first conductive bridge portion 120 and second conductive bridge portion 123 have no overlap. As shown in FIG. 1B, second dielectric layer 119 may be disposed in the outside region (e.g., outside the outer boarder ring region). In some embodiments, the end of second dielectric layer 119 that's facing the active region is vertically aligned with the end of first dielectric layer 116 that's facing away from the active region. In various embodiments, d5 can be less than, equal to, or greater than d6. In some embodiments, d5 is between about 1 μm and about 4 μm. In some embodiments, second dielectric layer 119 has a thickness t7 between about 40 nm and about 400 nm.

BAW structure 100, BAW structure 101 may include a second electrode 107 in contact with a bottom surface of piezoelectric layer 102, and a second insulating layer 113 in contact with second electrode 107. Similar to second electrode 106 in BAW structure 100, second electrode 107 may include a first metal layer 107-1 in contact with piezoelectric layer 102 and a second metal layer 107-2 in contact with first metal layer 107-1. The materials of first and second metal layers 107-1 and 107-2, and second insulating layer 113 may be similar to or the same as those of first and second material layers 106-1 and 106-2, and second insulating layer 112, and the detailed description is not repeated herein. Different from BAW structure 100, second electrode 107 and second insulating layer 113 may extend through active region, the recessed frame region, and the mass loading frame (e.g., beyond the outer boarder ring region). Second insulating layer 113 may stop at the boundary between the mass frame region and the outside region, where second conductive bridge portion 123 starts.

FIG. 1C illustrates simulated quality factors (as the y-axis) as functions of the width of the inner mass loading frame (as the x-axis) and length d3 of the outer boarder ring (as trellis), according to the embodiments of the present disclosure. The simulated quality factors of the “aligned bridges” (e.g., BAW structure 100) and “shifted bridges” (e.g., BAW structure 101) are comparable to existing BAW resonators without a conductive bridge.

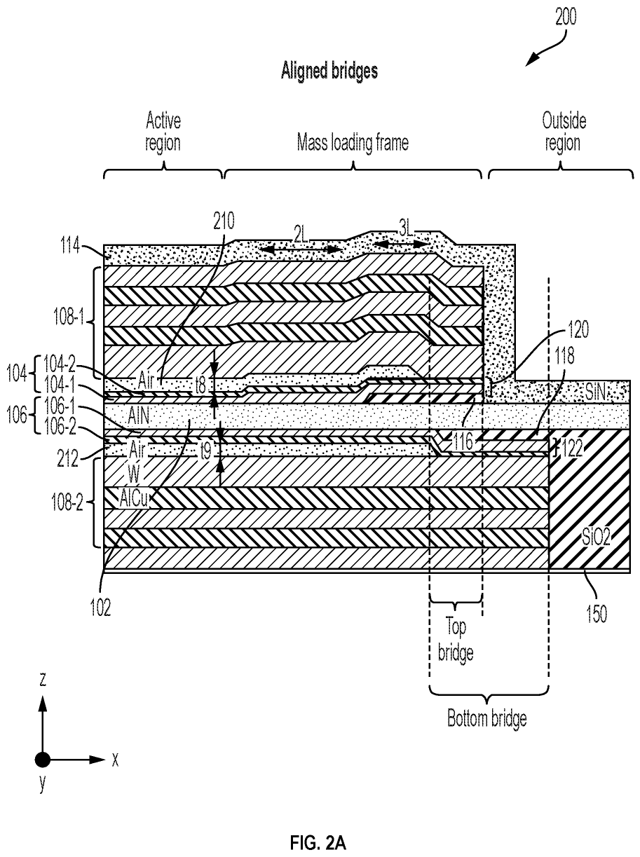

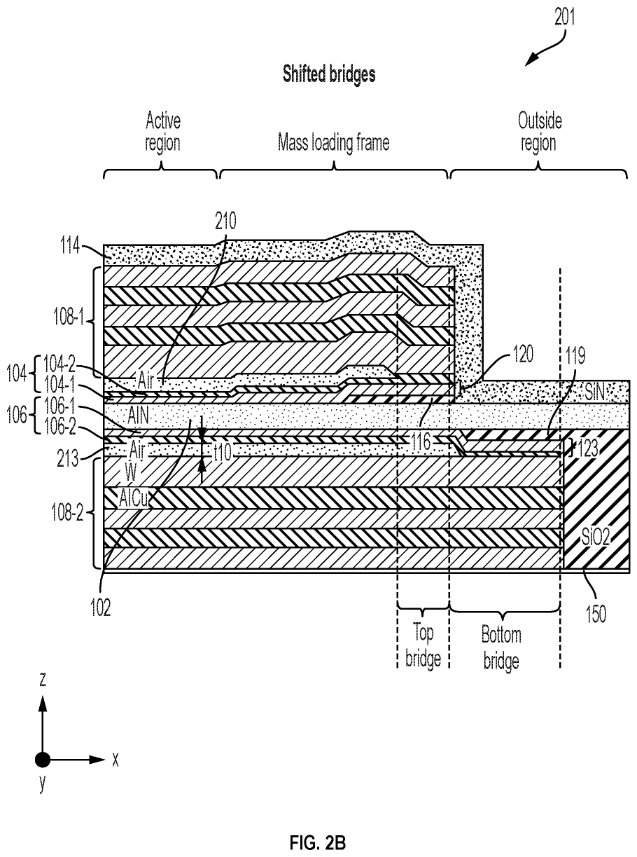

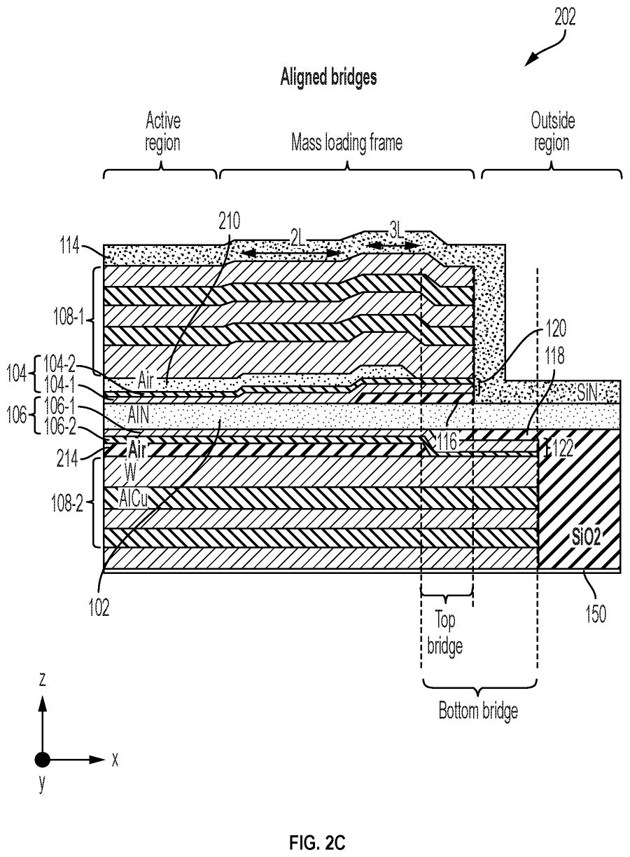

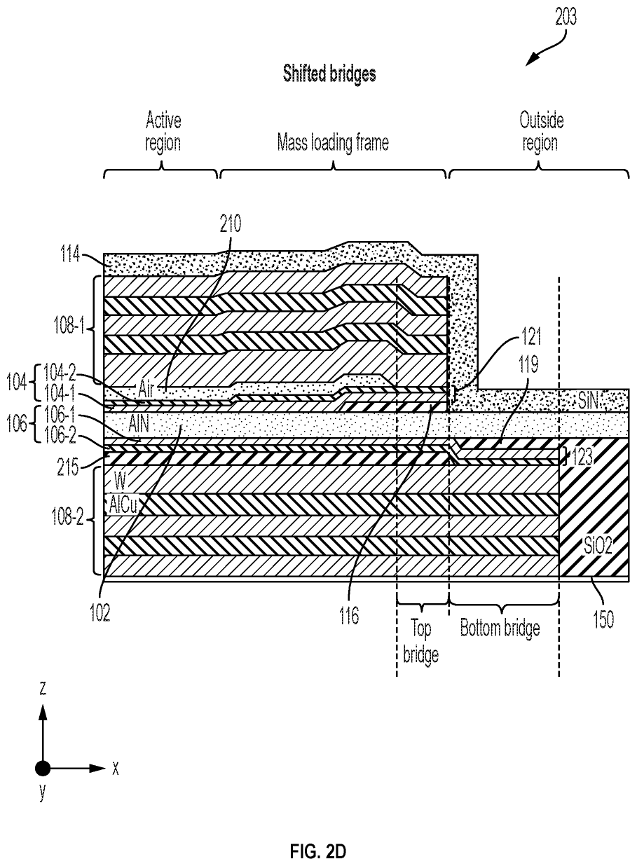

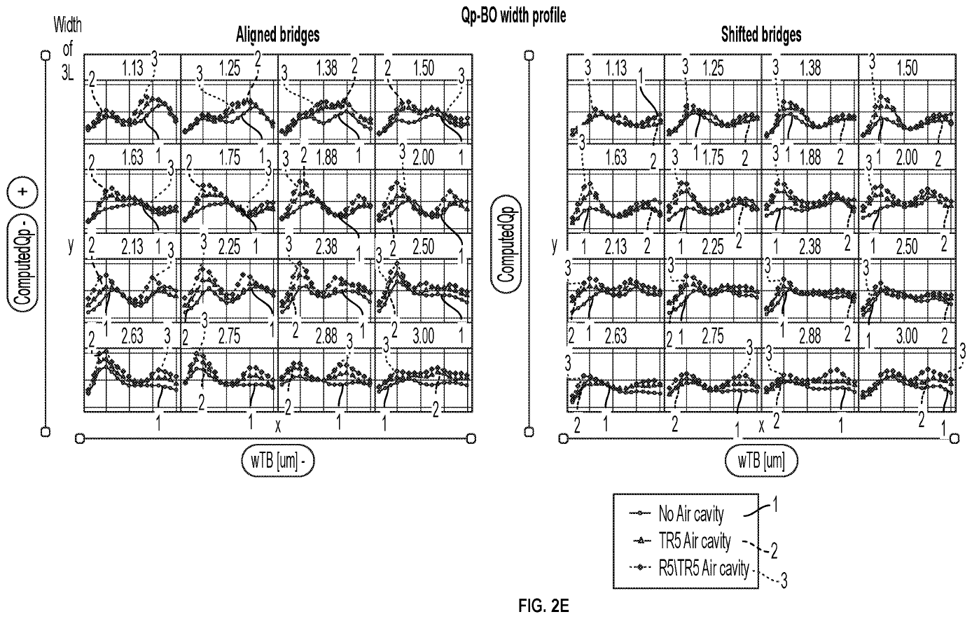

FIG. 2A illustrates another exemplary BAW structure 200, according to some embodiments of the present disclosure. BAW structure 200 may also have an “aligned bridges” configuration such that the vertical projections of first conductive bridge portion 120 and second conductive bridge portion 122 overlap. BAW 200 includes a first insulating layer 210 over first electrode 104, and a second insulating layer 212 over second electrode 106. Different from BAW 100, first insulating layer 210 and second insulating layer 212 may each include an air gap, e.g., an air cavity. The air gap can acoustically decouple the Bragg reflector stacks from the electrodes, and can maximize the acoustic energy storage in piezoelectric layer 102 and the electrodes 104 and 106, thus resulting in higher/improved acoustic coupling and quality factor. As shown in FIG. 2A, the air gap may be in the active region, and may extend into the mass loading frame (e.g., the inner and outer boarder ring regions). In some embodiments, the ends of first and second insulating layers 210 and 212, facing away from the active region, may vertically align with each other. In some embodiments, first insulating layer 210 has a thickness t8 similar to t3, and second insulating layer 212 has a thickness t9 similar to t5. In some embodiments, the thicknesses of first insulating layer 210 and second insulating layer 212 stay unchanged in the active region and the mass loading frame.

In some embodiments, different from BAW structure 100, BAW structure 200 does not include a recessed frame region. For example, the inner boarder ring region may be in contact with and surrounding the active region, as shown in FIG. 2A. In some embodiments, the length of the inner boarder ring region of BAW structure 200 may be equal to the sum of the recessed frame region and the inner boarder ring region of BAW structure 100 (e.g., (d1+d2)). First insulating layer 210 and second insulating layer 212 may extend into the inner boarder ring region from the active region, and further into the outer boarder ring region. In some embodiments, the thicknesses of first electrode 104 in the active region and the inner boarder ring region of BAW structure 200 may be similar to or the same as those of BAW structure 100. In some embodiments, the geometrical parameters (e.g., lengths, angles, etc.) of first conductive bridge portion 120, second conductive bridge portion 122, first dielectric layer 116, and second dielectric layer 118 may be similar to or the same as those of BAW structure 100, and the detailed description is not repeated herein.

FIG. 2B illustrates another exemplary BAW structure 201, according to some embodiments of the present disclosure. BAW structure 201 may also have an “shifted bridges” configuration such that the vertical projections of first conductive bridge portion 120 and second conductive bridge portion 123 have no overlap. BAW 201 includes a first insulating layer 210 over first electrode 104, and a second insulating layer 212 over second electrode 106. Different from BAW 101, first insulating layer 210 and second insulating layer 213 may each include an air gap, e.g., an air cavity. Similar to BAW structure 200, air gap can maximize the acoustic energy storage in piezoelectric layer 102 and the electrodes, thus resulting in higher/improved acoustic coupling and quality factor. The locations and dimensions of first insulating layer 210 of BAW structure 201 may be similar to or the same as those of BAW structure 200, and the detailed description is not repeated herein. Second insulating layer 213 may extend through the active region and the mass loading frame. Similar to BAW structure 200, BAW structure 201 does not include a recessed frame region. For example, the inner boarder ring region may be in contact with and surrounding the active region, as shown in FIG. 2B. In some embodiments, the length of the inner boarder ring region of BAW structure 201 may be equal to the sum of the recessed frame region and the inner boarder ring region of BAW structure 101 (e.g., (d1+d2)). In some embodiments, the thicknesses of first electrode 104 in the active region and the inner boarder ring of BAW structure 200 may be similar to or the same as those of BAW structure 101. In some embodiments, the geometrical parameters (e.g., thicknesses, angles, etc.) of first conductive bridge portion 120, second conductive bridge portion 123, first dielectric layer 116, and second dielectric layer 119 may be similar to or the same as those of BAW structure 101, and the detailed description is not repeated herein. In some embodiments, BAW structures 200 and 201 may each include a recessed frame region between the active region and the mass loading frame region. The recessed frame regions may have dimensions and shapes similar to those described in BAW structures 100 and 101 in FIGS. 1A and 1B, and may include an air gap.

FIG. 2C illustrates another exemplary BAW structure 202, according to some embodiments of the present disclosure. BAW structure 202 may also have an “aligned bridges” configuration similar to BAW structure 200. Different from BAW structure 200, BAW structure 202 includes a first insulating layer 210 that includes an air gap, and a second insulating layer 214 that includes a dielectric material, such as silicon oxide, silicon nitride, and/or silicon oxynitride. In some embodiments, second insulating layer 214 includes silicon oxide. In some embodiments, the geometrical parameters (e.g., thicknesses, angles, etc.) of other parts of BAW structure 202, such as first conductive bridge portion 120, second conductive bridge portion 122, first dielectric layer 116, and second dielectric layer 118 may be similar to or the same as those of BAW structure 200. The geometric parameters of second insulating layer 214 may be similar to second insulating layer 112. The detailed description is not repeated herein.

FIG. 2D illustrates another exemplary BAW structure 203, according to some embodiments of the present disclosure. BAW structure 203 may also have an “shifted bridges” configuration similar to BAW structure 201. Different from BAW structure 201, BAW structure 203 includes a first insulating layer 210 that includes an air gap, and a second insulating layer 215 that includes a dielectric material, such as silicon oxide, silicon nitride, and/or silicon oxynitride. In some embodiments, second insulating layer 215 includes silicon oxide. In some embodiments, the geometrical parameters (e.g., lengths, angles, etc.) of other parts of BAW structure 202, such as first conductive bridge portion 120, second conductive bridge portion 122, first dielectric layer 116, and second dielectric layer 119 may be like or the same as those of BAW structure 201. The geometric parameters of second insulating layer 215 may be similar to second insulating layer 113. The detailed description is not repeated herein.

FIG. 2E illustrates simulated quality factors as functions of the width of the inner BO (as the x-axis) and length d3 of the outer boarder ring (as trellis), according to the embodiments of the present disclosure. “No Air cavity” refers to the BAW structures without an air gap in the insulating layers (e.g., BAW structures 100 and 101); “TR5 Air cavity” refers to the BAW structures with one air cavity below the top fifth Brag reflector layer (e.g., BAW structures 202 and 203); and “R5 \TR5 Air cavity” refers to the BAW structures with two air cavities respectively below the top fifth Bragg reflector layer and above the bottom fifth Bragg reflector (e.g., BAW structures 200 and 201). The simulated quality factors of the “R5 /TR5 Air cavity” are generally higher than those of “TR5 Air cavity,” and the quality factors of “TR5 Air cavity” are generally higher than those of “No Air cavity” due to improved acoustic energy confinement.

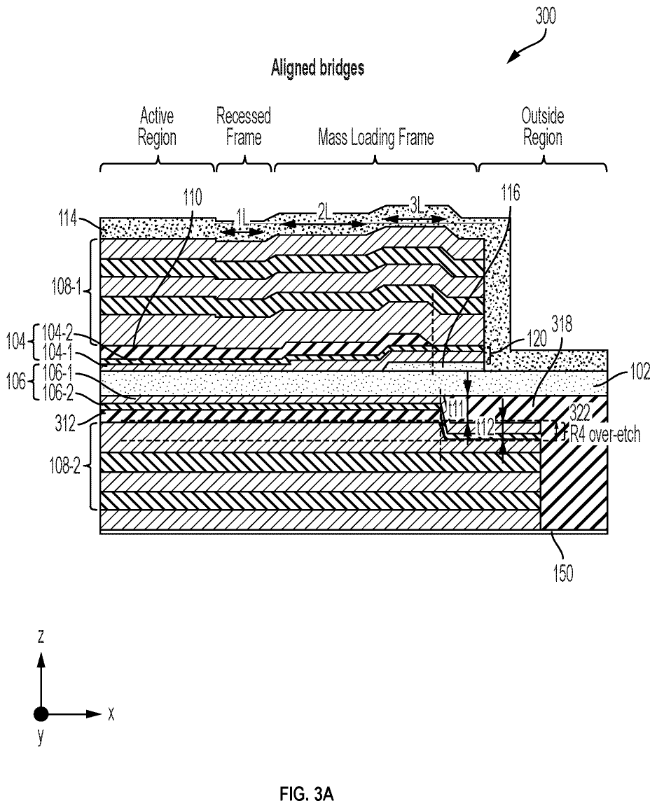

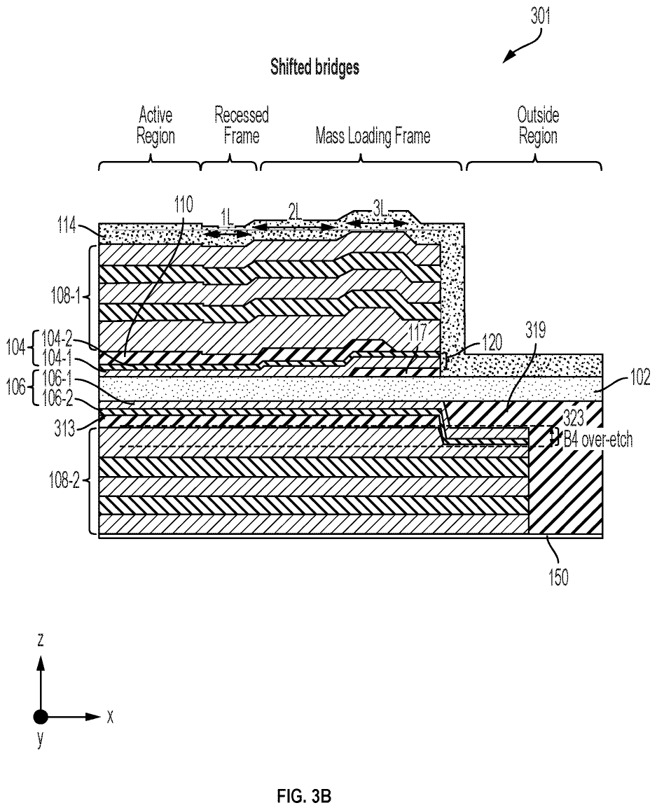

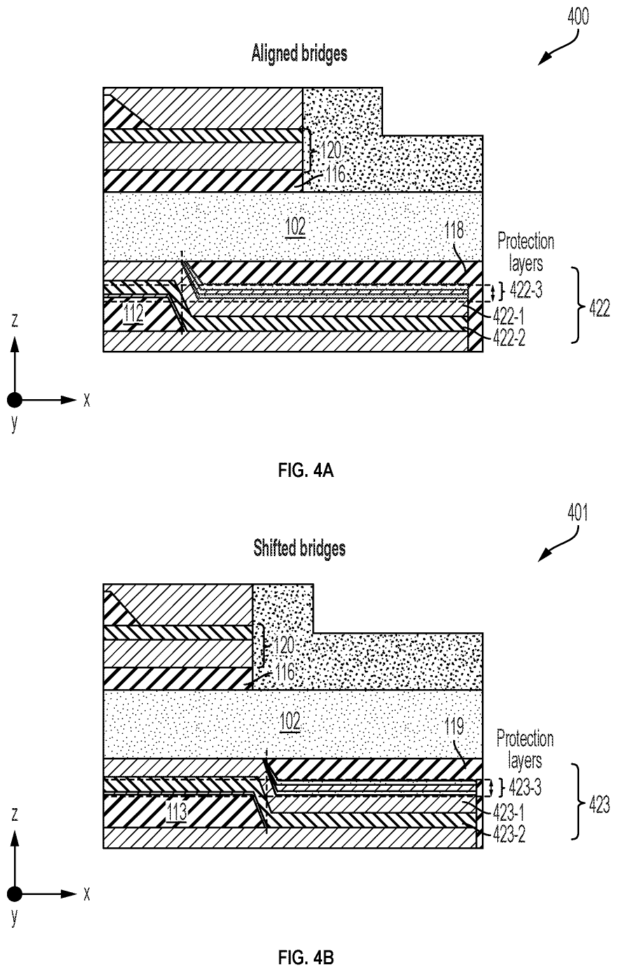

FIG. 3A illustrates another exemplary BAW structure 300, according to some embodiments of the present disclosure. BAW structure 300 have an “aligned bridges” configuration and may further reduce electrical loss. Different from BAW structure 100, BAW structure 300 may include a second dielectric layer 318 that is thicker than second dielectric layer 118. In some embodiments, a thickness t11 of second dielectric layer 318 is equal to about the sum of the total thicknesses of second electrode 106 and a second insulating layer 312. In some embodiments, thickness t11 of second dielectric layer 318 is between about 40 nm and about 1000 nm. BAW structure 300 may also have a second conductive bridge portion 322 that extends over (e.g., covers) second dielectric layer 318. As shown in FIG. 3A, a bottom surface of second conductive bridge portion 322 may be located between the top surface and the bottom surface of the first Bragg reflector layer (e.g., W) that is in contact with second insulating layer 312. Second insulating layer 312 may be similar to or different from second insulating layer 112. In some embodiments, second insulating layer 312 includes a portion that extends between the top and bottom surfaces of the first Bragg reflector layer. In some embodiments, a top surface of second conductive bridge portion 322 is coplanar with the bottom surface of second insulating layer 312. In some embodiments, a thickness t12 of second conductive bridge portion 322 is similar to or the same as that of second electrode 106. In BAW structure 300, the vertical projections of first conductive bridge portion 120 and second conductive bridge portion 322 overlap.
FIG. 3B illustrates another exemplary BAW structure 301, according to some embodiments of the present disclosure. BAW structure 301 have a “shifted bridges” configuration and may further reduce electrical loss. Different from BAW structure 101, BAW structure 301 may include a second dielectric layer 319 that is thicker than second dielectric layer 119. In some embodiments, a thickness of second dielectric layer 319 is equal to about the sum of the total thicknesses of second electrode 106 and a second insulating layer 313. In some embodiments, the thickness of second dielectric layer 319 is similar to that of second dielectric layer 318. BAW structure 301 may also have a second conductive bridge portion 323 that extends over (e.g., covers) second dielectric layer 319. As shown in FIG. 3B, a bottom surface of second conductive bridge portion 323 may be located between the top surface and the bottom surface of the first Bragg reflector layer (e.g., W) that is in contact with second insulating layer 313. In some embodiments, a top surface of second conductive bridge portion 323 is coplanar with the bottom surface of second insulating layer 313. In some embodiments, a thickness of second conductive bridge portion is similar to or the same as that of second conductive bridge portion 322. In BAW structure 301, the vertical projections of first conductive bridge portion 120 and second conductive bridge portion 323 do not overlap.
FIG. 4A illustrates another exemplary BAW structure 400, according to some embodiments of the present disclosure. BAW structure 400 may have an “aligned bridges” configuration, in which a second conductive bridge portion 422 fully covers second dielectric layer 118, and overlaps with first conductive bridge portion 120 in the vertical direction. Different from BAW structure 100, second conductive bridge portion 422 includes a first metal layer 422-1, a second metal layer 422-2 in contact with first metal layer 422-1, and one or more protection layers 422-3 in contact with first metal layer 422-1 and second dielectric layer 118. One or more protection layers 422-3 may include a single layer or multiple layers, and may include suitable material(s) that can provide protection for first metal layer 422-1 and second metal layer 422-2. In some embodiments, one or more protection layers 422-3 includes a layer of W sandwiched by two layers of AlN (e.g., a AlN-W-AlN structure). In some embodiments, one or more protection layers 422-3 can also include other suitable materials, such as carbon, silicon nitride, and the like. In some embodiments, the materials of first metal layer 422-1 and second metal layer 422-2 are similar to or the same as first metal layer 106-1 and second metal layer 106-2, respectively.

FIG. 4B illustrates another exemplary BAW structure 401, according to some embodiments of the present disclosure. BAW structure 401 may have a “shifted bridges” configuration, in which a second conductive bridge portion 423 covers second dielectric layer 119, and has no overlap with first conductive bridge portion 120 in the vertical direction. Different from BAW structure 101, second conductive bridge portion 423 includes a first metal layer 421-1, a second metal layer 423-2 in contact with first metal layer 423-1, and one or more protection layers 423-3 in contact with first metal layer 423-1 and second dielectric layer 119. One or more protection layers 423-3 may include a single layer or multiple layers, and may include suitable material(s) that can protect first metal layer 423-1 and second metal layer 423-2. In some embodiments, one or more protection layers 423-3 includes a layer of W sandwiched by two layers of AIN (e.g., a AIN-W-AIN structure). In some embodiments, one or more protection layers 423-3 can also include other suitable materials, such as carbon, silicon nitride, and the like. In some embodiments, the materials of first metal layer 423-1 and second metal layer 423-2 are similar to or the same as first metal layer 107-1 and second metal layer 107-2, respectively.

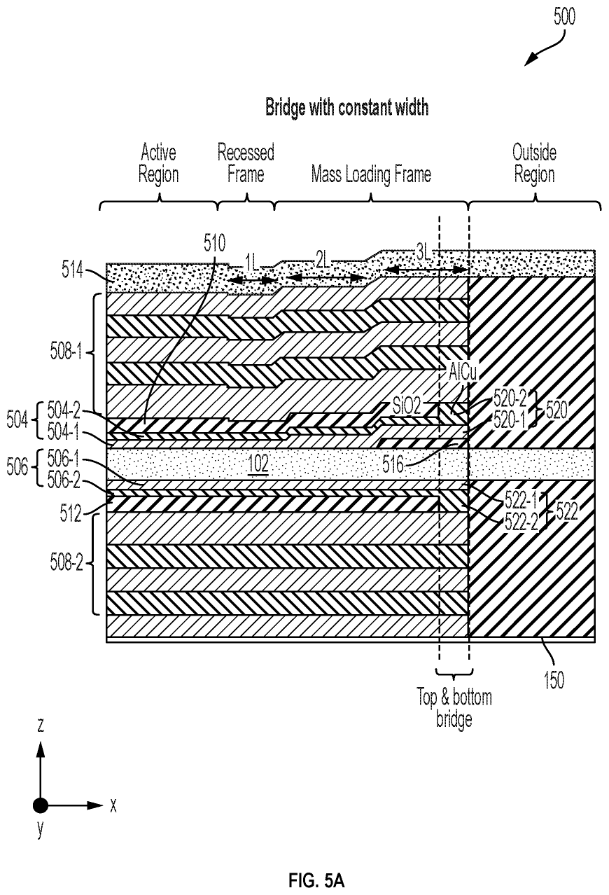

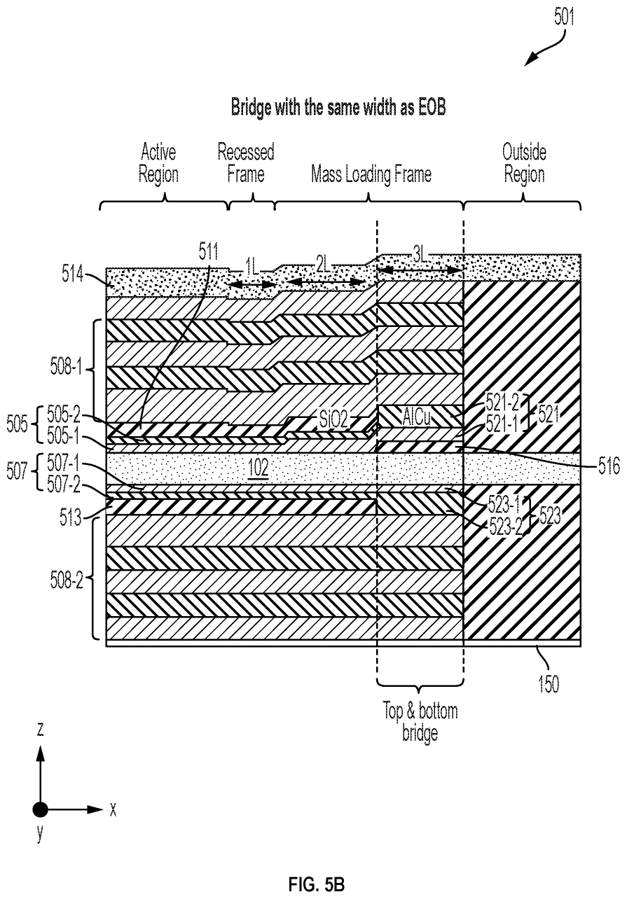

FIG. 5A illustrates another exemplary BAW structure 500, according to some embodiments of the present disclosure. BAW structure 500 may include a substrate 150, piezoelectric layer 102, a first electrode 504 and a second electrode 506 each over and in contact with piezoelectric layer 102, a first insulating layer 510, a second insulating layer 512, an upper Bragg reflector stack 508-1, a lower Bragg reflector stack 508-2, and a passivation layer 514. First electrode 504 may have a first metal layer 504-1 and a second metal layer 504-2; and second electrode 506 may have a first metal layer 506-1 and a second metal layer 506-2. The materials of these parts are similar to or the same as their counterparts in BAW structure 100, and the detailed description is not repeated herein. Different from BAW structure 100, BAW structure 500 includes a dielectric layer 516 in contact with the top surface of piezoelectric layer 102, similar to dielectric layer 216, but has no dielectric layer in contact with the bottom surface of piezoelectric layer 102. As shown in FIG. 5A, first insulating layer 510 may extend over dielectric layer 516 and may partially cover dielectric layer 516. Different from first insulating layer 110, a side surface of first insulating layer 510 aligns with the vertical direction (e.g., the z-direction). Second insulating layer 512 may also have a side surface that aligns with the vertical direction. In some embodiments, the side surfaces of first insulating layer 510 and second insulating layer 512 align with each other in the vertical direction. In some embodiments, BAW structure 500 includes an active region, a recessed frame region, a mass loading frame region, and an outside region. The lengths of the regions and the thicknesses of the layers in the regions may be similar to the counterparts in BAW 100, and the detailed description is not repeated herein.

BAW structure 500 may include a first conductive bridge portion 520 and a second conductive bridge portion 522, each being conductively connected with the respective Bragg reflector stack. As shown in FIG. 5A, BAW structure 500 may include a first portion 520-1 as an extension of first metal layer 504-1, and a second portion 520-2 as an extension of second metal layer 504-2. Different from BAW structure 100, second portion 520-2 may be in contact with the side surface of first insulating layer 510, and may include AlCu. In some embodiments, second portion 520-2 does not include any material (e.g., W) of the Bragg reflector layer in contact with first insulating layer 510 and may include only AlCu. In some embodiments, the top surface of second portion 520-2 is coplanar with the top surface of first insulating layer 510 in the outer boarder ring region. Second conductive bridge portion 522 may also include a first portion 521-1 as an extension of first metal layer 506-1, and a second portion 522-2 as an extension of second metal layer 506-2. Different from BAW structure 100, second portion 522-2 may be in contact with the side surface of second insulating layer 512, and may include AlCu. In some embodiments, second portion 522-2 does not include any material (e.g., W) of the Bragg reflector layer in contact with second insulating layer 512 and may include only AlCu. In some embodiments, the bottom surface of second portion 522-2 is coplanar with the bottom surface of second insulating layer 512. As shown in FIG. 5A, of first conductive bridge portion 520 and second conductive bridge portion 522, the side surfaces facing the active region may align with each other in the vertical direction, and the side surfaces facing away from the active region may align with each other. In other words, the bridge portions have a constant (e.g., same) width.

FIG. 5B illustrates another exemplary BAW structure 501, according to some embodiments of the present disclosure. BAW structure 500 may include a substrate 150, piezoelectric layer 102, a first electrode 505 and a second electrode 507 each over and in contact with piezoelectric layer 102, a first insulating layer 511, a second insulating layer 513, an upper Bragg reflector stack 508-1, a lower Bragg reflector stack 508-2, and a passivation layer 514. First electrode 505 may have a first metal layer 505-1 and a second metal layer 505-2; and second electrode 507 may have a first metal layer 507-1 and a second metal layer 507-2. The materials of these parts are similar to or the same as their counterparts in BAW structure 100, and the detailed description is not repeated herein. Similar to BAW structure 500, BAW structure 501 includes a dielectric layer 516 in contact with the top surface of piezoelectric layer 102, but has no dielectric layer in contact with the bottom surface of piezoelectric layer 102. Different from first insulating layer 110, first insulating layer 511 has no overlap with dielectric layer 516, and a side surface of first insulating layer 511 aligns with the vertical direction (e.g., the z-direction). Second insulating layer 512 may also have a side surface that aligns with the vertical direction. In some embodiments, the side surfaces of first insulating layer 511 and second insulating layer 513 align with each other in the vertical direction. As shown in FIG. 5B, the side surfaces of first insulating layer 511 and second insulating layer 513 are aligned with each other on the boundary of the outer boarder ring region.

BAW structure 501 may include a first conductive bridge portion 521 and a second conductive bridge portion 523, each being conductively connected with the respective Bragg reflector stack. As shown in FIG. 5B, BAW structure 501 may include a first portion 521-1 as an extension of first metal layer 505-1, and a second portion 521-2 as an extension of second metal layer 505-2. Different from BAW structure 100, second portion 521-2 may be in contact with the side surface of first insulating layer 511, and may include AlCu. In some embodiments, second portion 521-2 does not include any material (e.g., W) of the Bragg reflector layer in contact with first insulating layer 511 and may include only AlCu. In some embodiments, a length (e.g., in the x-direction) of second portion 521-2 (or first conductive bridge portion 521) is the same as the length of the outer boarder ring region (“3”), e.g., d3 as referring back to FIG. 1A. Second conductive bridge portion 523 may also include a first portion 523-1 as an extension of first metal layer 507-1, and a second portion 523-2 as an extension of second metal layer 507-2. Different from BAW structure 100, second portion 523-2 may be in contact with the side surface of second insulating layer 513, and may include AlCu. In some embodiments, second portion 523-2 does not include any material (e.g., W) of the Bragg reflector layer in contact with second insulating layer 513 and may include only AlCu. In some embodiments, the bottom surface of second portion 523-2 is coplanar with the bottom surface of second insulating layer 513. In some embodiments, a length of second portion 523-2 (or second conductive bridge portion 523) is the same as the length of the outer boarder ring region (“3”), e.g., d3 as referring back to FIG. 1A. As shown in FIG. 5B, of first conductive bridge portion 521 and second conductive bridge portion 523, the side surfaces facing the active region may align with each other in the vertical direction, and the side surfaces facing away from the active region may align with each other. In other words, the bridge portions each has a same width as the outer boarder ring region.

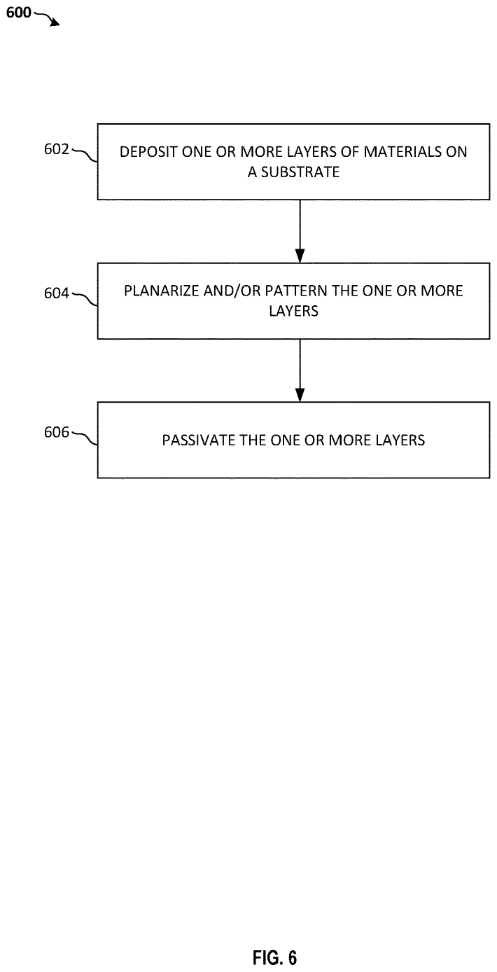

FIG. 6A is a flowchart of a method 600 for fabricating a BAW structure, according to some embodiments of the present disclosure. Method 600 is merely an example, and is not intended to limit the present disclosure beyond what is explicitly recited in the claims. Additional operations can be provided before, during, and after the method 600, and some operations described can be replaced, eliminated, or moved around for additional embodiments of method 600. Method 600 will be described in more detail below.

At step 602, one or more layers of materials may be deposited on a substrate. In some embodiments, one or more different materials may be deposited on a suitable substrate to form a plurality of layers for various functions. For example, a piezoelectric layer, a pair of electrodes, one or more insulating layers, one or more dielectric layers, and one or more Bragg reflector layers are deposited on the substrate. The materials may be deposited using one or more suitable deposition processes such as atomic layer deposition, chemical vapor deposition, physical vapor deposition, electroplating, electroless plating, or a combination thereof.

At step 604, the one or more layers may be planarized and/or patterned. Step 604 may be performed between the deposition of two layers of materials. The planarization process may include chemical mechanical polishing, etching, or a combination thereof.

At step 606, the one or more layers are passivated. After the deposition and planarization of layers are complete, a passivation layer is deposited on the exterior of the layers. The passivation layer may be deposited by chemical vapor deposition, physical vapor deposition, atomic layer deposition, or a combination thereof.

1. A bulk acoustic wave (BAW) resonator structure, comprising a transducer that comprises:
a first electrode;
a second electrode;
a piezoelectric layer between the first electrode and the second electrode;
a dielectric layer in contact with the piezoelectric layer on a surface of the piezoelectric layer;
a conductive layer over the first electrode; and
a conductive bridge portion in contact with the first electrode, the conductive layer, and over and in contact with the dielectric layer,
wherein the conductive bridge portion and the conductive layer form a conductive bridge structure between ends of the first electrode.

2. The BAW resonator structure of claim 1, wherein:
the conductive bridge portion is in contact with the first electrode, and comprises a same conductive material as the first electrode.

3. The BAW resonator structure of claim 1, wherein the transducer further comprises:
a second dielectric layer in contact with the piezoelectric layer on a second surface of the piezoelectric layer; and
a second conductive bridge structure over and in contact with the second dielectric layer, and in contact with the second electrode,
wherein the second conductive bridge structure comprises a same conductive material as the second electrode.

4. The BAW resonator structure of claim 3, wherein:
in a horizontal direction, a length of the conductive bridge portion is smaller than a length of the second conductive bridge portion;
in a vertical direction, a projection of the conductive bridge structure is partially overlapped with a projection of the second conductive bridge portion; and
a boundary between the conductive bridge portion and the first electrode is aligned with a boundary between the second conductive bridge portion and the second electrode.

5. The BAW resonator structure of claim 3, wherein:
in a horizontal direction, a length of the conductive bridge portion is smaller than a length of the second conductive bridge portion; and
in a vertical direction, a projection of the conductive bridge portion has no overlap with a projection of the second conductive bridge portion.

6. The BAW resonator structure of claim 3, wherein, in a vertical direction, a projection of the first electrode is partially overlapped with a projection of the dielectric layer; and
a projection of the second electrode has no overlap with a projection of the second dielectric layer.

7. The BAW resonator structure of claim 3, wherein:
the first electrode has a first thickness in an active region and a recessed frame region surrounding the active region, and has a second thickness outside the active region and the recessed frame region, the second thickness being greater than the first thickness; and
the second electrode has a same thickness in the active region, the recessed frame region, and outside the frame region.

8. The BAW resonator structure of claim 7, wherein the transducer further comprises a first insulating layer over and in contact with the first electrode in the active region and the recessed frame region, and
wherein the first insulating layer has a first thickness in the active region and a second thickness in the recessed frame region, the first thickness being greater than the second thickness.

9. The BAW resonator structure of claim 7, wherein the transducer further comprises a second insulating layer over and in contact with the second electrode in the active region and the recessed frame region, and
wherein the second insulating layer has a same thickness in the active region and the recessed frame region.

10. The BAW resonator structure of claim 3, wherein:
an angle between a side surface of the dielectric layer and a vertical direction is between about 30 degrees and about 60 degrees; and
an angle between a side surface of the second dielectric layer and the vertical direction is between about 5 degrees and about 15 degrees.

11. The BAW resonator structure of claim 8, wherein an angle between a side surface of the first insulating layer and a vertical direction is between about 30 degrees and about 50 degrees.

12. The BAW resonator structure of claim 9, wherein an angle between a side surface of the second insulating layer and a vertical direction is between about 5 degrees and about 15 degrees.

13. The BAW resonator structure of claim 1, wherein, in a vertical direction, a thickness of the dielectric layer is between about 20 nm and about 200 nm.

14. The BAW resonator structure of claim 3, wherein the transducer further comprises one or more insulating layers each in contact with a respective one of the first electrode and the second electrode, and wherein the one or more insulating layers each comprises an air gap.

15. The BAW resonator structure of claim 9, wherein the transducer further comprises a conductive layer in contact with the second insulating layer, and wherein in a vertical direction, a surface of the second conductive bridge portion is located between a first surface and a second surface of the conductive layer.

16. The BAW resonator structure of claim 3, wherein the transducer further comprises an aluminum nitride-tungsten-aluminum nitride structure located between the second dielectric layer and the second conductive bridge portion.

17. The BAW resonator structure of claim 3, wherein an angle between a side surface of the conductive bridge portion and a vertical direction is approximately zero, and an angle between a side surface of the second conductive bridge portion and the vertical direction is approximately zero.

18. The BAW resonator structure of claim 17, wherein in a vertical direction, a projection of the conductive bridge portion is aligned with a projection of the second conductive bridge portion.

19. The BAW resonator structure of claim 17, wherein the transducer further comprises an insulating layer over and in contact with at least one of the first and second electrode layers, the insulating layer being in contact with a respective conductive bridge portion, wherein an interface between the insulating layer and the respective conductive bridge portion is aligned with the vertical direction.

20. The BAW resonator structure of claim 1, wherein the transducer further comprises a pair of reflective layers over each of the first electrode and the second electrode and conductively connected to a respective conductive bridge that is in contact with the respective electrode, and
wherein the pair of reflective layers comprises a tungsten layer and an aluminum copper layer.
